(19) United States
(12) Patent Application Publication
(10) Pub. No.: US 2026/0327785 A1
(43) Pub. Date: Oct. 22, 2026

(54) SUBSTRATE PROCESSING SYSTEM FOR PROCESSING OF A PLURALITY OF SUBSTRATES AND METHOD OF PROCESSING A SUBSTRATE IN AN IN-LINE SUBSTRATE PROCESSING SYSTEM

(71) Applicant: Applied Materials, Inc., Santa Clara, CA (US)

(72) Inventors: Dieter HAAS, Santa Clara, CA (US); Jürgen HENRICH, Limeshain (DE); Sebastian Gunther ZANG, Grossostheim (DE); Henning AUST, Mühltal (DE); Jörg SCHULER, Wiesbaden (DE); Takashi ANJIKI, Aschaffenburg (DE)

(21) Appl. No.: 18/875,879

(22) PCT Filed: Oct. 19, 2022
(86) PCT No.: PCT/IB2022/060048

§ 371 Date: Dec. 17, 2024

Related U.S. Application Data
(60) Provisional application No. 63/357,971, filed on Jul. 1, 2022.

(51) Int. Cl. C23C 14/56; C23C 14/04; C23C 14/24; C23C 14/54; H10K 71/16

(52) U.S. Cl. CPC C23C 14/568; C23C 14/042; C23C 14/24; C23C 14/54; H10K 71/164

(57) ABSTRACT

A substrate processing system for processing of a plurality of substrates is described. The substrate processing system includes one or more vacuum chambers; at least a first deposition source provided in the one or more vacuum chambers, the first deposition source providing a first deposition area in a first angular direction; at least a first idle shield associated with the first deposition source configured to block evaporated material in a second angular direction of the first deposition source; a substrate transportation track configured to move, by a translation, a first substrate of the plurality of substrates through the first deposition area; and a shield transportation track between the substrate transportation track and the first deposition source configured to move, by a translation, a shield back and forth between a first shield position of 15 the first deposition area and a second shield position of the first deposition area.

### TECHNICAL FIELD

Embodiments of the present disclosure relate to a substrate processing system, particularly an in-line substrate processing system. Further, embodiments of the present disclosure relate to a system and a method to evaporate an OLED layer stack in a vertical orientation. Embodiments of the present disclosure particularly relate to a substrate processing system for processing of a plurality of substrates, such as a substrate processing system for processing of a plurality of large area substrates in an essentially vertical orientation, a method of processing a substrate in an in-line substrate processing system, and a method of manufacturing a layer stack of a display on a large area substrate.

### BACKGROUND

Organic light-emitting diodes (OLED) are a special type of light-emitting diode in which the emissive layer includes a thin-film of certain organic compounds. OLEDs are used in the manufacture of television screens, computer monitors, mobile phones, other hand-held devices, etc. for displaying information. OLEDs can also be used for general space illumination. The range of colors and brightness possible with OLED displays is greater than that of traditional LCD displays because OLED material directly emits light. The energy consumption of OLED displays is considerably less than that of traditional LCD displays.

Further, the fact that OLEDs can be manufactured onto flexible substrates results in further applications. An OLED display may include, for example, layers of organic material situated between two electrodes, for example electrodes made of a metallic material. The OLED is typically placed between two glass panels, and the edges of the glass panels are sealed to encapsulate the OLED therein. Alternatively, the OLED can be encapsulated with thin film technology, e.g. with a barrier film.

A process to manufacture OLED displays includes thermal evaporation of organic materials and deposition of organic materials on a substrate in a high vacuum. The process utilizes an edge exclusion mask in order to block substrate areas, for example, the edge of the substrate, from being coated. The substrate is arranged behind the mask during deposition.

Considering a tendency towards larger substrate sizes for display manufacturing, it is beneficial to provide an improved system and improved method for depositing an organic layer stack.

### SUMMARY

In light of the above, a substrate processing system for processing of a plurality of substrates, a method of processing a first substrate of a plurality of substrates in an in-line substrate processing system, and a method of manufacturing a layer stack of a display on a large area substrate are provided. Further aspects, embodiments, features and details can be derived from the dependent claims, the drawings and the specification.

According to an embodiment, a substrate processing system for processing of a plurality of substrates is provided. The substrate processing system includes one or more vacuum chambers; at least a first deposition source provided in the one or more vacuum chambers, the first deposition source providing a first deposition area in a first angular direction; at least a first idle shield associated with the first deposition source configured to block evaporated material in a second angular direction of the first deposition source; a substrate transportation track configured to move, by a translation, a first substrate of the plurality of substrates through the first deposition area; and a shield transportation track between the substrate transportation track and the first deposition source configured to move, by a translation, a shield back and forth between a first shield position of the first deposition area and a second shield position of the first deposition area.

According to an embodiment, a method of processing a first substrate of a plurality of substrates in an in-line substrate processing system is provided. The method includes moving, by translation, the first substrate on a first substrate carrier in one or more vacuum chambers along a substrate transportation track in a first substrate position associated with a first deposition source; moving, by translation, a shield in a first shield position configured to protect at least a portion of at least one of the first substrate and the first substrate carrier to be coated by the first deposition source; moving, by a translation, the first substrate on the first substrate carrier and the shield, wherein the first substrate is moved through a first deposition area of the first deposition source for depositing material on the first substrate, wherein the first substrate is moved to a second substrate position and the shield is moved to a second shield position, the second shield position being configured to protect at least a portion of at least one of the first substrate and the first substrate carrier to be coated by the first deposition source; and moving, by a translation, the shield from the second shield position back to the first shield position.

According to an embodiment, a method of manufacturing a layer stack of a display on a large area substrate is provided. The method includes a method of processing a substrate in an in-line processing system according to any of the embodiments described herein, wherein, at least, a first layer of the layer stack is deposited by the first deposition source and a second layer of the layer stack is deposited by the second deposition source.

According to an embodiment, a substrate processing system for processing of a plurality of substrates is provided. The system includes: one or more vacuum chambers; at least a first deposition source and a second deposition source provided in the one or more vacuum chambers, the first deposition source providing a first deposition area in a first angular direction; a substrate transportation track configured to move, by a translation, a first substrate of the plurality of substrates through the first deposition area; a shield transportation track configured to move, by a translation, a shield; and a controller with a memory including instructions and with a processor, wherein the instructions, when executed by the processor, cause the substrate processing system to execute a method according to any of the embodiments described herein.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments and are described in the following:

FIG. 1 shows a schematic top view of an in-line evaporation system according to embodiments of the present disclosure;

FIGS. 2A to 2G show schematic top views of a processing chamber illustrating various processing conditions according to embodiments of the present disclosure and as, for example, described with respect to FIG. 3;

FIG. 3 shows a flowchart illustrating a method to manufacture an organic layer stack according to embodiments described herein;

FIGS. 4A and 4B show schematic views of relative positions between a substrate carrier, a movable shield and a deposition source according to embodiments of the present disclosure;

FIGS. 5A and 5B show schematic views of a movable shield that can be utilized for embodiments of the present disclosure; and

FIGS. 6A to 6E show schematic side views of various processing conditions according to embodiments of the present disclosure.

### DETAILED DESCRIPTION OF EMBODIMENTS

Reference will now be made in detail to the various embodiments, one or more examples of which are illustrated in the figures. Within the following description of the drawings, the same reference numbers refer to same components. Generally, only the differences with respect to individual embodiments are described. Each example is provided by way of explanation and is not meant as a limitation of the disclosure. Further, features illustrated or described as part of one embodiment can be used on or in conjunction with other embodiments to yield yet a further embodiment. It is intended that the description includes such modifications and variations.

A process to manufacture OLED displays can include thermal evaporation of organic materials and deposition of organic materials on a substrate in a high vacuum. Depending on the display technology, the use of a mask for patterning the organic layers onto the substrate during deposition may be provided or patterning may be provided without a fine metal mask. An edge exclusion mask or a shield, e.g. a movable shield, can be provided to block evaporated material from reaching a substrate carrier and, optionally, an edge of the substrate to be processed. For example, a mask may be an edge exclusion mask or a movable shield masking the perimeter of a glass substrate, such as the rectangular glass substrate, e.g. with an edge of a few millimeters.

Embodiments of the present disclosure relate to substrate processing systems and substrate processing apparatuses, particularly in-line systems and in-line apparatuses for depositing material subsequently on a plurality of substrates. A movable edge exclusion mask or movable shield for in-line processing is provided. A specific movable edge exclusion mask or movable shield is associated and/or can be stored for the specific deposition source.

According to some embodiments, which can be combined with other embodiments described herein, methods to reduce an edge exclusion distance for dynamic deposition systems by dynamically adjusting the shield position with reference to the substrate position, particularly for entry and exit of the deposition zone, i.e. a processing area are provided.

According to an embodiment, a substrate processing system for processing of a plurality of substrates is provided. The substrate processing system includes one or more vacuum chambers and at least a first deposition source and, optionally, a second deposition source, provided in the one or more vacuum chambers. The first deposition source provides a first deposition area in a first angular direction and, optionally, a second deposition source provides a second deposition area. At least a first idle shield is associated with the first deposition source configured to block evaporated material in a second angular direction of the first deposition source. The system further includes a substrate transportation track configured to move, by a translation, a first substrate of the plurality of substrates through the first deposition area and, optionally, the second deposition area; and a shield transportation track between the substrate transportation track and the first deposition source configured to move, by a translation, a shield back and forth between a first shield position of the first deposition area and a second shield position of the first deposition area.

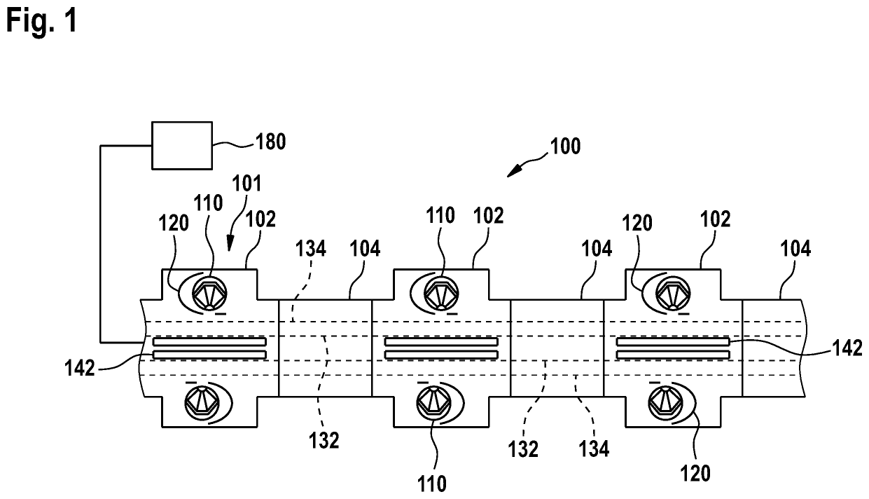

FIG. 1 shows a substrate processing system 100. The substrate processing system 100 shown in FIG. 1 includes a plurality of vacuum chambers. The one or more vacuum chambers can include a vacuum processing chamber 102 and a vacuum transfer chamber 104. FIG. 1 shows three vacuum processing chambers and three vacuum transfer chambers. A vacuum processing chamber 102 is included in a substrate processing apparatus 101. A glass handling module (not shown) can be provided at one end of the substrate processing system 100. The glass handling module can load and/or unload substrates into the vacuum processing chamber. Further, a rotation module (not shown), for example, a vacuum rotation module, can be provided at a second end of the substrate processing system, which is distal to the mask handling module.

The substrate processing system as shown in FIG. 1 is an in-line substrate processing system. Substrates to be processed in the substrate processing system 100 are loaded at the glass handling module, for example, on substrate carriers, and are unloaded at the glass handling module, for example from substrate carriers. Substrates can be transported on the first substrate transportation track 132 in one direction, for example, from left to right in FIG. 1. The substrate can be rotated in a rotation module and transferred to a second substrate transportation track 132. The substrates can be transported, for example, from right to left on the second substrate transportation track to be unloaded at the glass handling module. Accordingly, an empty carrier is provided after unloading of a processed substrate at the same position, at which a new substrate is to be loaded on the empty carrier. Thus, transportation of empty carriers, for example, on a carrier return path can be avoided or reduced to a minimum. Further, exposure of a carrier to an atmospheric condition can be avoided or reduced to a minimum. Further, the rotation module allows for folding the substrate processing system. As exemplarily shown in FIG. 1, the substrate processing system can include a forward transportation path on a first substrate transportation track 132 for depositing a first group of material layers, for example organic layers, on the substrate and a backward transportation path on the second substrate transportation track 132 for depositing a second group of material layers over the first group of material layers. The substrate is rotated between the forward transportation path and the backward transportation path by the rotation module. By “folding” the substrate processing system, the length of the substrate processing system can be reduced.

The substrate processing system shown in FIG. 1 further includes a shield transportation track 134, and particularly the first shield transportation track 134 in a forward transportation path and the second shield transportation track 134 in a backward transportation path. The shield transportation track 134 is provided between the substrate transportation track 132 and a deposition source 110. The shield transportation track is configured to move the shield in front of the deposition area.

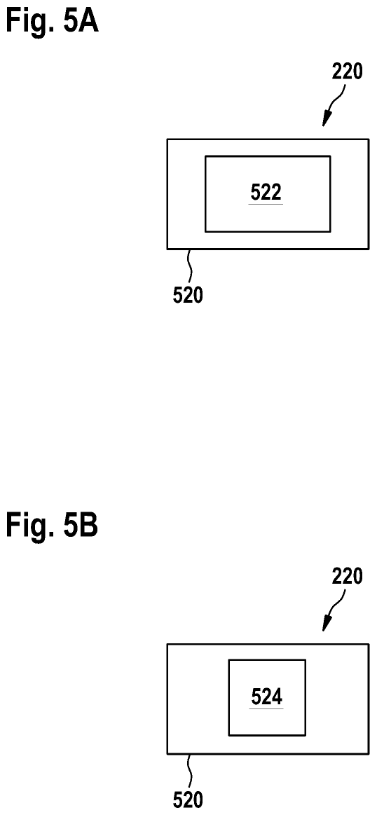

According to embodiments of the present disclosure, reference is made to an edge exclusion mask and/or a shield. A shield as described herein can be understood as a mask having a material blocking region and an aperture within the material blocking region. The aperture has a size to cover at least a portion of the substrate carrier, and particularly to cover the substrate carrier to avoid or reduce material deposition on the substrate carrier during substrate processing. As described in more detail with respect to FIGS. 5A and 5B, the size of the aperture of the shield can be configured to shield a small portion of a substrate, e.g. an edge portion of the substrate having a dimension of a few millimeters, at least in one substrate dimension. Further, the aperture can have a size smaller than the substrate along a second substrate dimension to shield an edge portion of the substrate, i.e. an edge portion of a few millimeters, also in the second substrate dimension. Accordingly, a shield as referred to herein can also be referred to as an edge exclusion mask. However, according to various embodiments, a shield may be an edge exclusion mask along only one substrate dimension or a shield may only substantially block the substrate carrier from material deposition.

The in-line substrate processing system can be a display manufacturing system or a part of a display manufacturing system, in particular an OLED display manufacturing system, and more particularly an OLED display manufacturing system for large area substrates. The transport of a mask, for example, on a mask carrier, or substrate carrier, i.e. the movement of a substrate carrier through the in-line substrate processing system can, for example, be provided in a vertically orientated state of the substrate carrier. For example, substrate carriers can be configured to hold a substrate, such as a glass plate, in a vertically orientated state or a substantially vertically orientated state.

According to some embodiments, which can be combined with other embodiments described herein, the substrate carriers can be configured for holding or supporting the substrate or the substrate and the mask in a substantially vertical orientation. Further, a mask carrier can be configured for holding or supporting the mask in a substantially vertical orientation. As used throughout the present disclosure, “vertical” or “substantially vertical” is understood particularly when referring to the substrate orientation, to allow for a deviation from the vertical direction or orientation of ±20° or below, e.g. of ±10° or below. The deviation can be provided for example because a substrate support with some deviation from the vertical orientation might result in a more stable substrate position. Further, fewer particles reach the substrate surface when the substrate is tilted forward. Yet, the substrate orientation, e.g., during the deposition of materials, such as organic or metallic materials, on a substrate in a high vacuum, is considered substantially vertical, which is considered different from the horizontal substrate orientation, which may be considered as horizontal ±20° or below.

As shown in FIG. 1, a substrate transportation track 132 can be provided. Further, a shield transportation track 134 can be provided. According to some embodiments, a substrate transportation track and/or a shield transportation track can be configured for contactless transportation of a substrate carrier. The contactless transportation may be a magnetic levitation system. In particular, the magnetic levitation system may be provided so that at least a part of the weight of a substrate carrier and/or a shield carrier is carried by the magnetic levitation system. The carriers can then be guided essentially in a contactless manner along a substrate transportation track through the in-line substrate processing system. The carriers can then be guided essentially in a contactless manner along a shield transportation track back and forth in the in-line substrate processing system In particular, the transportation may include a carrier holding structure and carrier driving structure. A carrier holding structure can be configured for contactless holding of a carrier. A carrier driving structure can be configured for a contactless translation of a carrier. A carrier holding structure may include a magnetic levitation system for contactless holding of a substrate carrier. Further, a carrier driving structure may include a magnetic drive system for contactless driving of a carrier. Other transportation means, e.g. on rollers, or with passive magnetic elements may also be provided.

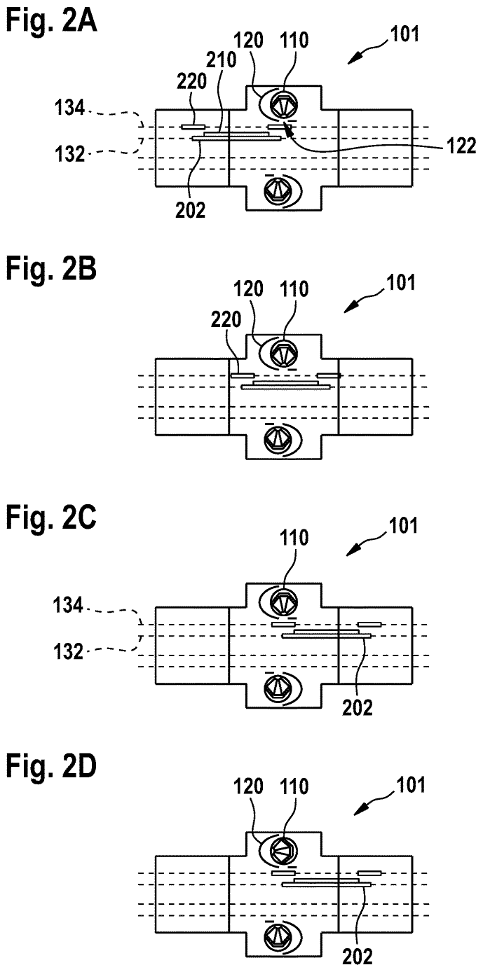

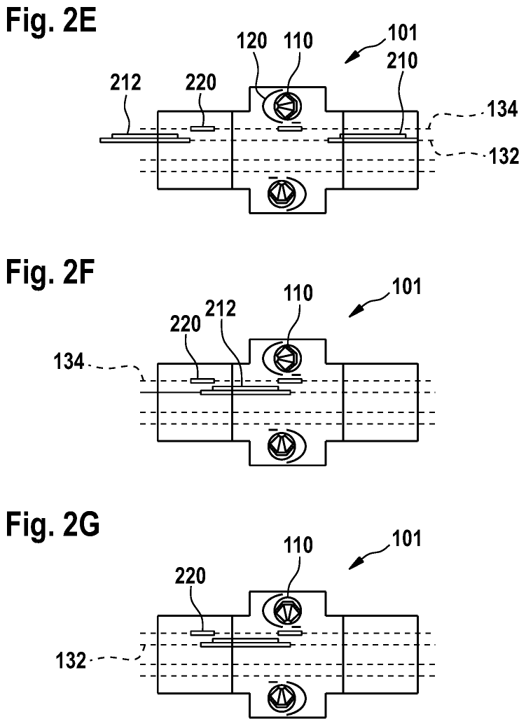

A substrate processing apparatus 101, as exemplarily shown in FIG. 1, can include a forward transportation path. The forward transportation path includes a substrate transportation track 132 and a shield transportation track 134. For example, the forward transportation path may be the upper transportation paths in FIG. 1, wherein a substrate is transported from left to right through the substrate processing system 100. A deposition source 110 is provided in the vacuum processing chamber 102. Further, an idle shield 120 is provided. The idle shield is configured to block evaporated material, i.e. material evaporated from the deposition source 110. As described in more detail with respect to FIGS. 2A to 2G, the deposition source 110 can be rotated, for example, clockwise in FIG. 1, into an idle position. In the idle position, the evaporated material is blocked by the idle shield 120. In the rotational position shown in FIG. 1, material evaporated by the deposition source 110 can pass through an aperture 122 in the idle shield 120 in order to deposit material on a substrate.

For example, the deposition source 110 can be an organic deposition source. The deposition source is provided in vacuum processing chambers of the substrate processing apparatus 101. According to some embodiments, which can be combined with other embodiments described herein, the one or more deposition sources in the substrate processing system 100 can be evaporation sources, and particularly line sources extending essentially vertically. Organic material can be deposited on a substrate, for example, while the substrate moves past a deposition source 110 providing a line source. According to some embodiments, which can be combined with other embodiments described herein, one or more of the deposition sources may also be a metal source and/or inorganic source, for example for manufacturing a cathode of a device.

According to some embodiments, which can be combined with other embodiments described herein, an in-line substrate processing system may include at least one transportation path. For example, the forward transportation path, i.e. the upper path in FIG. 1, can be provided. Optionally, as shown in FIG. 1, a second transportation path having a second substrate transportation track 132 and the second shield transportation track 134 can be provided. Accordingly, the substrate processing apparatus 101 can include a first deposition source 110 in the vacuum processing chamber 102 and a second deposition source 110 in the vacuum processing chamber 102. According to some embodiments, which can be combined with other embodiments described herein, the forward transportation paths and the backward transportation path can be separated with one or more protection shields 142. The protection shields 142 separate the forward transportation path from the backward transportation path to allow for, for example, the deposition of different materials in the vacuum processing chamber 102.

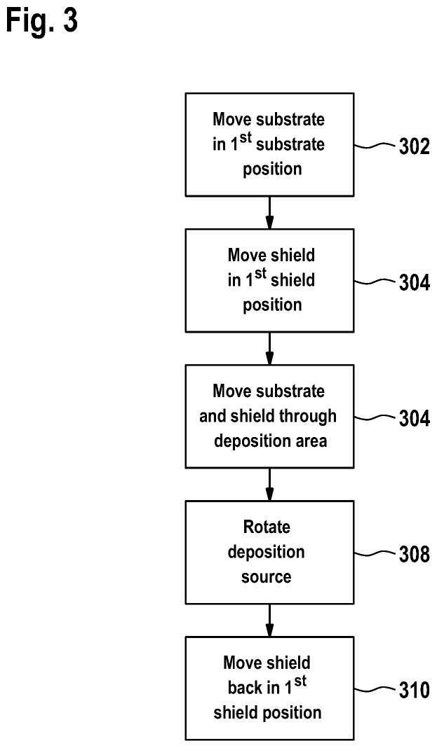

Methods of operating a substrate processing system and a method of processing a substrate according to embodiments of the present disclosure are described with respect to FIGS. 2A to 2G and FIG. 3. According to operation 302, the first substrate is moved in the first substrate position. The first substrate position is associated with a first deposition source 110. As shown in FIG. 2A, the substrate 210 can be provided on the substrate carrier 202. The substrate in FIGS. 2A to 2G is moved from left to right along the substrate transportation track. The substrate is moved by translation, and particularly in a vertical orientation. According to operation 304, the shield 220 is moved in a first shield position. As shown in FIG. 2A, the first shield position is configured to protect at least a portion of the substrate and/or the substrate carrier from being coated. In the first shield position, the substrate 210 can be coated through the aperture of the shield 220.

As shown in FIG. 2B, and according to operation 306, the substrate 210 and the shield 220 are moved through a deposition area of the deposition source 110 for substrate processing. Material can be deposited on the substrate while the substrate and the shield are moved from left to right in FIG. 2B. The substrate carrier and optionally a portion of the substrate, for example, an edge of the substrate is protected from being coated by the shield 220. As shown in FIG. 2C, after processing of the substrate 210, the substrate, e.g. supported by the substrate carrier 202, is in a second substrate position relative to the deposition area of the deposition source 110. The shield 220 is in a second shield position. At operation 308 and as shown in FIG. 2D, the deposition source 110 is rotated such that the plume of evaporated material is directed towards the idle shield 120. As shown in FIG. 2E, the first substrate 210 is moved further along the transportation path, for example, towards a further deposition source 110. The shield 220 is associated with the deposition source 110 and is moved back to the first shield position (see operation 310). As shown in FIG. 2E, the shield 220 can await a second substrate 212 in the first shield position.

According to an embodiment, a method of processing a first substrate of a plurality of substrates in an in-line substrate processing system is provided. The method includes moving, by translation, the first substrate on a first substrate carrier in one or more vacuum chambers along a substrate transportation track in a first substrate position associated with a first deposition source; moving, by translation, a shield in a first shield position configured to protect at least a portion of at least one of the first substrate and the first substrate carrier to be coated by the first deposition source; moving, by a translation, the first substrate on the first substrate carrier and the shield, wherein the first substrate is moved through a first deposition area of the first deposition source for depositing material on the first substrate, wherein the first substrate is moved to a second substrate position and the shield is moved to a second shield position, the second shield position being configured to protect at least a portion of at least one of the first substrate and the first substrate carrier to be coated by the first deposition source; moving, by a translation, the first substrate towards a second deposition area of a second deposition source; and moving, by a translation, the mask from the second shield position back to the first shield position.

According to methods described herein, a method for processing a substrate includes depositing material on the first substrate while the substrate is moved through the first deposition area of the first deposition source, the first deposition source being in a first angular direction can be provided. For example, the first angular direction corresponds to a source rotation, wherein material passes through the aperture 122 of the idle shield 120. According to some embodiments, which can be combined with other embodiments described herein, a method of processing a substrate may further include rotating the first deposition source from the first angular direction to a second angular direction, wherein evaporated material is blocked by an idle shield in the second angular direction.

As shown in FIG. 2F, the shield 220 and the second substrate 212 can be moved in the substrate processing system, such that the shield 220 is in the first shield position and the second substrate is in the first substrate position. Thereafter, the deposition source 110 can be rotated from the second rotational position to the first rotational position, as illustrated in FIG. 2G. FIG. 2G corresponds to FIG. 2A, wherein a second substrate is in the first position. Accordingly, by repeating the sequence described above, a method can include moving, by a translation, a second substrate on a second substrate carrier and the shield, wherein the second substrate is moved through the first deposition area of the first deposition source for depositing material on the second substrate. The first substrate on the first substrate carrier may be moved towards a further shield (not shown in FIGS. 2A to 2G), which can be associated with a second deposition source. The substrate can be moved through the second deposition area of the second deposition source for depositing material on the first substrate.

As described above, at initial operation, the edge exclusion mask or shield, particularly a shield carrier is in a starting position before deposition together with the substrate carrier (see e.g. FIG. 2A). According to some embodiments, which can be combined with other embodiments described herein, the shield carrier and the substrate carrier can move synchronized with each other (see e.g. FIGS. 2B and 2C). After the deposition is finished, the deposition source 110 rotates into an idle position relative to the idle shield, i.e. the deposition source rotates into the idle shield (see e.g. FIG. 2D). For example, the idle position can be the second angular direction. This enables that the shield carrier and/or the substrate carrier can be further transferred. The substrate carrier can move forward to a further source. The shield carrier stays at the deposition source 110 and moves back to the starting position (see e.g. FIG. 2E). The deposition source rotates back into the process position to restart the process with a further substrate (see FIG. 2G). According to some embodiments, which can be combined with other embodiments described herein, the aperture 122 of the idle shield 120 may have a size sufficiently large such that some material may be deposited into the vacuum processing chamber 102. Accordingly, the shield may move in correlation with the rotation of the deposition source in order to block material of the deposition source 110 during rotation of the deposition source. The shield may assist the idle shield in protecting the chamber components. Undesired coating of interior chamber walls can be reduced or avoided.

FIG. 1 shows a controller 180, which is connected to the substrate processing system 100. The controller 180 includes a central processing unit (CPU), a memory and, for example, support circuits. To facilitate control of the apparatus and/or system for substrate processing, the CPU may be one of any form of general purpose computer processor that can be used in an industrial setting for controlling various chambers and sub-processors. The memory is coupled to the CPU. The memory, or a computer readable medium, may be one or more readily available memory devices such as random access memory, read only memory, hard disk, or any other form of digital storage either local or remote. The support circuits may be coupled to the CPU for supporting the processor in a conventional manner. The circuits include cache, power supplies, clock circuits, input/output circuitry and related subsystems, and the like. Substrate processing instructions are generally stored in the memory as a software routine typically known as a recipe. The software routine may also be stored and/or executed by a second CPU (not shown) that is remotely located from the hardware being controlled by the CPU. The software routine, when executed by CPU, transforms the general purpose computer into a specific purpose computer (controller) that controls the apparatus operation and/or system operation such as that for shield transfer, substrate transfer, and deposition source rotation. Although the method and/or process of the present disclosure is discussed as being implemented as a software routine, some of the method steps that are disclosed therein may be performed in hardware as well as by the software controller. As such, embodiments of the invention may be implemented in software as executed upon a computer system, and hardware as an application specific integrated circuit or other type of hardware implementation, or a combination of software and hardware.

The controller may execute or perform a method of processing a substrate, particularly in an in-line substrate processing system. The controller may further execute or perform a method of manufacturing a layer stack of a display on a large area substrate. The method of manufacturing a layer stack of a display on a large area substrate includes a method of processing a substrate in an in-line processing system according to any of the embodiments described herein, wherein a first layer of the layer stack is deposited by the first deposition source and a second layer of the layer stack is deposited by the second deposition source.

According to an embodiment, an apparatus and/or system for processing a substrate according to any of the methods described herein is provided. The apparatus and/or system may include the controller 180. The controller includes a processor and a memory, the memory storing instructions that, when executed by the processor, cause the apparatus to perform a method according to embodiments of the present disclosure.

According to an embodiment, a substrate processing system for processing of a plurality of substrates is provided. The substrate processing system includes one or more vacuum chambers; at least a first deposition source and a second deposition source provided in the one or more vacuum chambers, the first deposition source providing a first deposition area in a first angular direction and the second deposition source providing a second deposition area; a substrate transportation track configured to move, by a translation, a first substrate of the plurality of substrates through the first deposition area and the second deposition area; a shield transportation track configured to move, by a translation, a shield; and a controller with a memory including instructions and with a processor, wherein the instructions, when executed by the processor, cause the substrate processing system to execute a method according to any of the embodiments described herein.

According to an embodiment, a substrate processing system for processing of a plurality of substrates is provided. The substrate processing system includes one or more vacuum chambers and at least a first deposition source and a second deposition source, which are provided in the one or more vacuum chambers. The first deposition source provides a first deposition area in a first angular direction and the second deposition source provides a second deposition area. The substrate processing system further includes at least a first idle shield associated with the first deposition source configured to block evaporated material in a second angular direction of the first deposition source; a substrate transportation track configured to move, by a translation, a first substrate of the plurality of substrates through the first deposition area and the second deposition area; and a shield transportation track between the substrate transportation track and the first deposition source configured to move, by a translation, a shield back and forth between a first shield position of the first deposition area and a second shield position of the first deposition area. According to some embodiments, the first deposition source can be in a fixed position along a substrate transportation track direction. Particularly, the first deposition source can be rotatable in the fixed position of the first deposition source.

According to some embodiments, which can be combined with other embodiments described herein, the substrate processing system can further include at least a second idle shield associated with the second deposition source configured to block evaporated material in a second angular direction of the second deposition source, wherein the shield transportation track extends towards the second deposition source to be between the substrate transportation track and the second deposition source and configured to move, by a translation, a further shield back and forth between a first shield position of the second deposition area and a second shield position of the second deposition area. For example, the second deposition source can be in a fixed position along a substrate transportation track direction, particularly wherein the second deposition source is rotatable in the fixed position of the second deposition source.

According to some embodiments, which can be combined with other embodiments described herein, a substrate carrier can be an electrostatic chuck (E-chuck) providing an electrostatic force for holding the substrate and optionally the mask at the substrate carrier, and particularly at the support surface. For example, the substrate carrier includes an electrode arrangement configured to provide an attracting force acting on the substrate.

The embodiments described herein can be utilized for deposition of materials, such as organic, inorganic or metallic materials, on large area substrates, e.g., for OLED display manufacturing. Specifically, the substrates, for which the structures and methods according to embodiments described herein are provided, may be large area substrates. For instance, a large area substrate can be GEN 4.5, which corresponds to a surface area of about 0.67 m² (0.73 m×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a glass plate or other substrates. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

As described above, according to some embodiments, the shield and the substrate or a shield carrier and the substrate carrier, respectively, can move synchronized with each other. This is particularly possible for a symmetric arrangement of a shield and an aperture 122 corresponding essentially to the size of the substrate. According to some embodiments, which can be combined with other embodiments described herein, the shield and the substrate can be moved independent from each other and at least partially at different velocities.

According to some embodiments, which can be combined with other embodiments described herein, the substrate can be provided on a substrate carrier and the shield can be provided on a shield carrier, i.e. individual carriers, particularly with independent position control, can be provided. Accordingly, the carriers can be dynamically moved during deposition. While the source is not moving, the edge of the substrate and the shield can move relative to each other. As compared to having a fixed shield-carrier relation, and for example, a moving source, the amount of edge exclusion can be reduced, for example, to the half of a width as compared to other implementations. For example, the shield to substrate distance, i.e. an edge exclusion width, particularly in a horizontal direction, can be reduced to 10 mm or below. According to some embodiments, which can be combined with other embodiments described herein, a shield position relative to the substrate can be dynamically adjusted. Accordingly, both carrier movements and part tolerances can be provided to be in such a range by adjustment of the relative positions.

According to some embodiments, which can be combined with other embodiments described herein, methods according to the present disclosure can reduce edge exclusion distance for dynamic deposition systems by dynamically adjusting shield carrier position difference in reference to the substrate position, particularly for entry and exit of a deposition zone or processing area.

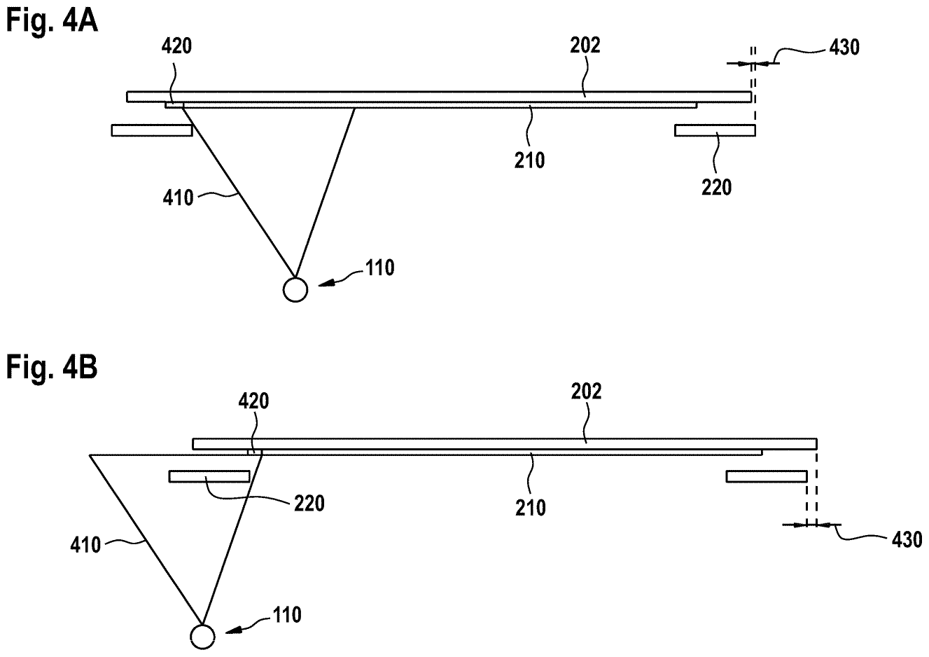

FIGS. 4A and 4B illustrate an adjustment of the relative position between the shield 220 and the substrate 210. The substrate can be supported on the substrate carrier 202. Further, the shield 220 can be supported on a shield carrier (not shown). The protected edge area 420 at the edge of the substrate is shown relative to the plume 410 of material evaporated from the deposition source 110. As shown in FIGS. 4A and 4B, the plume 410 can be asymmetric. In a first position of the substrate 210 relative to the plume, which is exemplarily shown in FIG. 4A, a relative position 430 between the substrate 210 and the shield 220 is provided. Due to the asymmetry of the plume, in order to maintain the same protected edge area 420, the relative position 430 between the substrate 210 and the shield 220 changes. Accordingly, moving the shield and the substrate independent of each other allows for improved control of the size of the protected edge area.

FIG. 5A shows a first example of a shield 220. The shield 220 has a shield body 520 with an opening 522. According to some embodiments, the opening 522 may essentially correspond to the size of the substrate. According to some embodiments, which can be combined with other embodiments described herein, the shield can have an opening being from 0 mm to 15 mm smaller than a substrate size in a first substrate dimension and a second substrate dimension different from the first substrate dimension. If the opening is 0 mm smaller than the substrate, i.e. the opening has the same size, the substrate carrier is protected from being coated. If the opening is a few millimeters smaller than the substrate size, the substrate carrier and an edge portion of the substrate can be protected from being coated.

FIG. 5B shows another example of a shield 220. The opening 524 in the shield body 520 has a size similar to the opening 522 described with respect to FIG. 5A in one direction, particularly a vertical direction. In a second direction, particularly a horizontal direction i.e. a carrier moving direction, the size of the opening 522 is smaller than the substrate size. According to some embodiments, which can be combined with other embodiments described herein, the shield can have an opening being from 0 mm to 15 mm smaller than a substrate size in a first substrate dimension and being smaller than a substrate size in a second substrate dimension extending in a horizontal direction. For example, the size of the opening 524 in a horizontal direction may correspond to the width of the plume 410 of evaporated material.

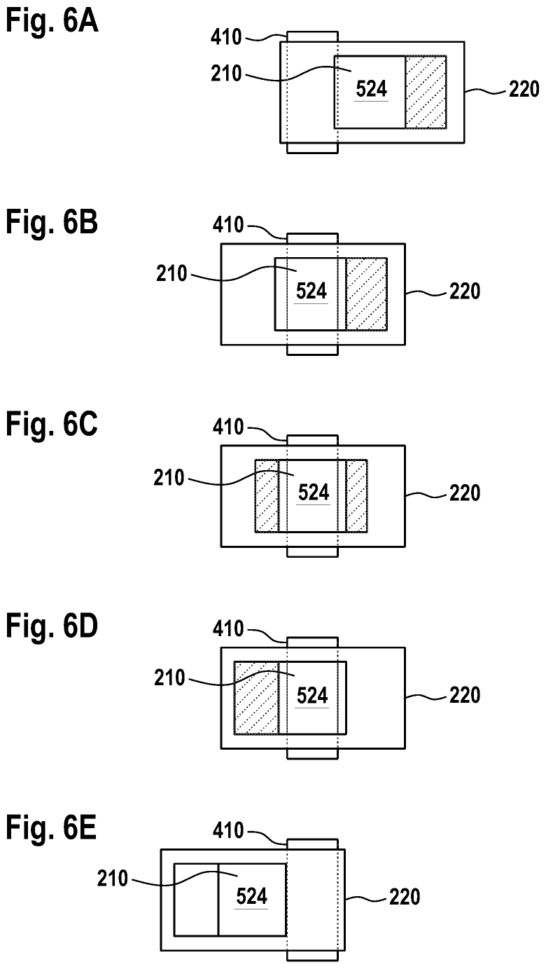

A relative movement of the shield 220, a substrate 210, and the material plume 410 is shown in FIGS. 6A to 6E. In FIG. 6A, the material, i.e. the plume 410 of material is directed onto the shield body of the shield 220. The substrate carrier is protected. The opening 524 and the substrate 210 have a first relative position with respect to each other. Both the substrate carrier and the movable shield can accelerate, for example to a constant velocity. The substrate and the shield are moved until the position is reached, in which the opening 524 allows for evaporated material to pass through the opening. For example, the opening 524 can be centered with respect to the plume 410 of evaporated material. This is shown in FIG. 6B. As shown in FIG. 6C, the substrate carrier can continue to move, for example at a constant velocity. The movable shield decelerates and may stop or move at a decreased velocity. The substrate carrier movement continues until relative positions as shown in FIG. 6D have been reached. Thereafter, the movable shield may accelerate to move together with the substrate carrier, for example, at a constant velocity and/or the same velocity as the substrate carrier. This results in relative positions as shown in FIG. 6E, wherein the substrate carrier and the movable shield may stop.

In light of the above, one or more of the following advantages can be provided by embodiments of the present disclosure. A movable shield can be provided for protecting the substrate carrier and/or an edge of a substrate. The particle generation can be reduced. As the movable shield is associated with a deposition source, material mixing can be reduced or avoided. The procedure of individual shields, e.g. per deposition source, further allows for a source specific scan speed, i.e. a source specific translation movement speed through the deposition area. The deposition rate can be adjusted for a deposition source by the scan speed.

While the foregoing is directed to some embodiments, other and further embodiments may be devised without departing from the scope, and the scope is determined by the claims that follow.

1. A substrate processing system for processing of a plurality of substrates, comprising:
one or more vacuum chambers;
at least a first deposition source provided in the one or more vacuum chambers, the first deposition source providing a first deposition area in a first angular direction;
at least a first idle shield associated with the first deposition source configured to block evaporated material emitted in a second angular direction of the first deposition source;
a substrate transportation track configured to move, by a translation, a first substrate of the plurality of substrates through the first deposition area; and
a shield transportation track between the substrate transportation track and the first deposition source configured to move, by a translation, a shield back and forth between a first shield position of the first deposition area and a second shield position of the first deposition area.

2. The substrate processing system according to claim 1, wherein the first deposition source is in a fixed position along a substrate transportation track direction and relative to the first deposition source.

3. The substrate processing system according to claim 2, wherein the first deposition source is rotatable in the fixed position of the first deposition source.

4. The substrate processing system according to claim 1, further comprising:
a second deposition source provided in the one or more vacuum chambers, the second deposition source providing a second deposition area, wherein the substrate transportation track is configured to move, by a translation, a first substrate of the plurality of substrates through the first deposition area and the second deposition area.

5. The substrate processing system according to claim 4, further comprising:
at least a second idle shield associated with the second deposition source configured to block evaporated material in a second angular direction of the second deposition source, wherein the shield transportation track extends towards the second deposition source to be between the substrate transportation track and the second deposition source and configured to move, by a translation, a further shield back and forth between a first shield position of the second deposition area and a second shield position of the second deposition area.

6. The substrate processing system according to claim 5, wherein the second deposition source is in a fixed position along a substrate transportation track direction and relative to the second deposition source, and wherein the second deposition source is rotatable in the fixed position of the second deposition source.

7. A method of processing a first substrate of a plurality of substrates in an inline substrate processing system, comprising:
moving, by translation, the first substrate on a first substrate carrier in one or more vacuum chambers along a substrate transportation track in a first substrate position associated with a first deposition source;
moving, by a translation, a shield in a first shield position configured to protect at least a portion of at least one of the first substrate and the first substrate carrier to be coated by the first deposition source;
moving, by a translation, the first substrate on the first substrate carrier and the shield, wherein the first substrate is moved through a first deposition area of the first deposition source for depositing material on the first substrate, wherein the first substrate is moved to a second substrate position and the shield is moved to a second shield position, the second shield position being configured to protect at least a portion of at least one of the first substrate and the first substrate carrier to be coated by the first deposition source; and
moving, by a translation, the shield from the second shield position back to the first shield position.

8. The method according to claim 7, wherein the shield has an opening being from 0 mm to 15 mm smaller than a substrate size in a first substrate dimension and a second substrate dimension different from the first substrate dimension.

9. The method according to claim 7, wherein the shield has an opening being from 0 mm to 15 mm smaller than a substrate size in a first substrate dimension and has an opening smaller than a substrate size and larger than the plume width of the first deposition source in a second substrate dimension extending in a carrier moving direction.

10. The method according to claim 7, wherein the shield and the first substrate are moved independent from each other and at least partially at different velocities.

11. The method according to claim 7, further comprising:
depositing material on the first substrate while the first substrate is moved through the first deposition area of the first deposition source, the first deposition source being in a first angular direction.

12. The method according to claim 11, further comprising:
rotating the first deposition source from the first angular direction to a second angular direction, wherein evaporated material is blocked by an idle shield in the second angular direction.

13. The method according to claim 7, further comprising:
moving, by a translation, the first substrate towards a second deposition area of a second deposition source.

14. The method according to claim 13, further comprising:
moving, by a translation, a second substrate on a second substrate carrier and the shield, wherein the second substrate is moved through the first deposition area of the first deposition source for depositing material on the second substrate; and
moving, by a translation, the first substrate on the first substrate carrier and a further shield, wherein the first substrate is moved through the second deposition area of the second deposition source for depositing material on the first substrate.

15. A method of manufacturing a layer stack of a display on a large area substrate, comprising:
a method of processing a substrate in an in-line processing system comprising:
moving, by translation, the first substrate on a first substrate carrier in one or more vacuum chambers along a substrate transportation track in a first substrate position associated with a first deposition source;
moving, by a translation, a shield in a first shield position configured to protect at least a portion of at least one of the first substrate and the first substrate carrier to be coated by the first deposition source;
moving, by a translation, the first substrate on the first substrate carrier and the shield, wherein the first substrate is moved through a first deposition area of the first deposition source for depositing material on the first substrate, wherein the first substrate is moved to a second substrate position and the shield is moved to a second shield position, the second shield position being configured to protect at least a portion of at least one of the first substrate and the first substrate carrier to be coated by the first deposition source; and
moving, by a translation, the shield from the second shield position back to the first shield position
wherein, at least, a first layer of the layer stack is deposited by the first deposition source and a second layer of the layer stack is deposited by the second deposition source.

16. A substrate processing system for processing of a plurality of substrates, comprising:
one or more vacuum chambers;
at least a first deposition source provided in the one or more vacuum chambers, the first deposition source providing a first deposition area in a first angular direction;
a substrate transportation track configured to move, by a translation, a first substrate of the plurality of substrates through the first deposition area;
a shield transportation track configured to move, by a translation, a shield; and
a controller with a memory comprising instructions and with a processor, wherein the instructions, when executed by the processor, cause the substrate processing system to execute a method of processing a substrate in an in-line processing system, the method comprising:
moving, by translation, the first substrate on a first substrate carrier in one or more vacuum chambers along a substrate transportation track in a first substrate position associated with a first deposition source;
moving, by a translation, a shield in a first shield position configured to protect at least a portion of at least one of the first substrate and the first substrate carrier to be coated by the first deposition source;
moving, by a translation, the first substrate on the first substrate carrier and the shield, wherein the first substrate is moved through a first deposition area of the first deposition source for depositing material on the first substrate, wherein the first substrate is moved to a second substrate position and the shield is moved to a second shield position, the second shield position being configured to protect at least a portion of at least one of the first substrate and the first substrate carrier to be coated by the first deposition source; and
moving, by a translation, the shield from the second shield position back to the first shield position.
